(19) United States
(12) Patent Application Publication
(10) Pub. No.: US 2018/0240912 A1
(43) Pub. Date: Aug. 23, 2018

(54) THIN FILM TRANSISTOR AND MANUFACTURING METHOD THEREOF

(71) Applicants: KUNSHAN NEW FLAT PANEL DISPLAY TECHNOLOGY CENTER CO., LTD., KunShan City, Jiangsu (CN); KUNSHAN GO-VISIONOX OPTO-ELECTRONICS CO., LTD., KunShan City, Jiangsu (CN)

(72) Inventors: Jingxun ZHAO, KunShan City, Jiangsu (CN); Fanzhong BU, KunShan City, Jiangsu (CN); Lei XU, KunShan City, Jiangsu (CN); Rui GUO, KunShan City, Jiangsu (CN)

(21) Appl. No.: 15/753,922

(22) PCT Filed: Aug. 15, 2016
(86) PCT No.: PCT/CN2016/095231

§ 371 Date: Feb. 20, 2018

(30) Foreign Application Priority Data
Aug. 19, 2015 (CN) 201510511335.4

(51) Int. Cl. H01L 29/786; H01L 29/06; H01L 29/08; H01L 21/02

(52) U.S. Cl. CPC H01L 29/78696; H01L 21/0262; H01L 29/0847; H01L 29/0649

(57) ABSTRACT

A thin film transistor (TFT) and a method of manufacturing the TFT are disclosed. The TFT (200) includes: a gate (21) formed on a substrate (20); an insulating laminate (23) formed on the gate (21); a semiconductor layer (25) formed on the insulating laminate (23); and a source (27) and a drain (29) formed on the semiconductor layer (25), the source (27) and the drain (29) being located at and connected to opposing lateral edges of the semiconductor layer (25). The insulating laminate (23) includes a first insulating layer (231) and a second insulating layer (232), the second insulating layer (232) being located between the first insulating layer (231) and the semiconductor layer (25). The dual-layer insulating laminate enables improvements in the performance of the TFT by enhancing the interface properties and repairing interface state defects in the semiconductor layer.

### TECHNICAL FIELD

The present invention relates to the field of transistors and, in particular, to thin film transistors (TFTs) and methods of manufacturing such TFTs.

### BACKGROUND

Thin film transistors (TFTs) are widely used as switching elements in various flat panel display devices including liquid crystal displays (LCDs) and organic light-emitting diode displays (OLEDs). Existing flat panel display devices usually incorporate an array of TFTs to drive the individual pixels of the display device.

Reference is now made to FIG. 1, a structural illustration of a thin film transistor of the prior art. As shown in FIG. 1, the conventional thin film transistor 100 includes: a gate 11 on a substrate 10; an insulating layer 13 on the gate 11; a semiconductor layer 15 on the insulating layer 13; and a source 17 and a drain 19 both on the semiconductor layer 15. The source 17 and the drain 19 are formed on and connected to respective lateral edges of the semiconductor layer 15.

In order to obtain high quality display of images, the thin film transistor 100 is required to have good electrical characteristics. The interface between the insulating layer 13 and the semiconductor layer 15 is designed to transfer electrons, and its performance is therefore critical to the electrical characteristics of the thin film transistor 100.

The insulating layer 13 is usually formed of tetraethyl orthosilicate (TEOS), silicon oxide (SiOₓ) or silicon nitride (SiNₓ) by chemical vapor deposition (CVD). Currently, most manufacturers are attempting to improve the performance of the interface by adjusting the deposition conditions for the insulating layer 13.

However, the existing TFTs are far from satisfactory in terms of electrical characteristics because they are suffering from a high off-state current (I_{off}), great sub-threshold swing (SS) factor, low mobility and other problems. These problems cannot be improved with process adjustments. The unsatisfactory TFT electrical characteristics fall short in meeting the requirements for high display quality of display devices.

Therefore, there is an urgent need in this art to solve the problem of inability of the existing TFTs' inferior electrical characteristics to meet the requirements for high display quality.

### SUMMARY OF THE INVENTION

It is an objective of the present invention is to provide thin film transistors (TFTs) and methods for fabricating the TFTs, which can address the problem of inability of the existing TFTs' inferior electrical characteristics to meet the requirements for high display quality.

To this end, in a first aspect of the present invention, there is provided a thin film transistor (TFT), including: a gate formed on a substrate; an insulating laminate formed on the gate; a semiconductor layer formed on the insulating laminate; and a source and a drain formed on the semiconductor layer, the source and the drain are located at and connected to opposing lateral edges of the semiconductor layer, wherein the insulating laminate includes a first insulating layer and a second insulating layer, the second insulating layer is located between the first insulating layer and the semiconductor layer.

Optionally, in the TFT, the first insulating layer may be a tetraethyl orthosilicate layer, with the second insulating layer being a silicon oxynitride layer. Alternatively, the first insulating layer may be a silicon oxynitride layer, with the second insulating layer being a tetraethyl orthosilicate layer.

Optionally, in the TFT, each of the first insulating layer and the second insulating layer may be formed by a chemical vapor deposition process.

Optionally, in the TFT, each of the first insulating layer and the second insulating layer may have a thickness comprised between 1 nm and 80 nm.

In a second aspect of the present invention, there is provided a method of fabricating the TFT as defined above. The method includes:

providing a substrate and forming a gate on the substrate;

forming a first insulating layer on the gate by a first chemical vapor deposition (CVD) process;

forming a second insulating layer on the first insulating layer by a second CVD process;

forming a semiconductor layer on the second insulating layer; and

forming a source and a drain on the semiconductor layer.

Optionally, in the method, the first insulating layer may be a tetraethyl orthosilicate layer, with the second insulating layer being a silicon oxynitride layer. Alternatively, the first insulating layer may be a silicon oxynitride layer, with the second insulating layer being a tetraethyl orthosilicate layer.

Optionally, in the method, the first or second CVD process for forming the tetraethyl orthosilicate layer may use oxygen (O₂) as a working gas.

Optionally, in the method, the first or second CVD process for forming the silicon oxynitride layer may use a mixed gas of SiH₄, NH₃, N₂ and N₂O as a working gas.

Optionally, in the method, NH₃ may be present in the mixed gas at a molar ratio included between 0.8 and 0.96.

Optionally, in the method, each of the first insulating layer and the second insulating layer may have a thickness comprised between 1 nm and 80 nm.

In a third aspect of the present invention, there is provided a TFT, including: a semiconductor layer formed on a substrate; an insulating laminate formed on the semiconductor layer; a gate formed on the insulating laminate; a dielectric layer covering the gate; and a source and a drain formed on the dielectric layer, the source and the drain are located at opposing later edges of the gate and penetrate through the dielectric layer and the insulating laminate to connect to the semiconductor layer, wherein the insulating laminate includes a first insulating layer and a second insulating layer, and wherein the first insulating layer is located between the second insulating layer and the semiconductor layer.

In a fourth aspect of the present invention, there is provided a method of fabricating the TFT as defined above. The method includes:

providing a substrate and forming a semiconductor layer on the substrate;

forming a first insulating layer on the semiconductor layer by a first chemical vapor deposition (CVD) process;

forming a second insulating layer on the first insulating layer by a second CVD process;

forming a gate on the second insulating layer;

forming a dielectric layer covering the gate;

etching the dielectric layer, the second insulating layer and the first insulating layer and forming contact holes at opposing lateral edges of the gate, the contact holes leading to the semiconductor layer; and

filling metal(s) in the contact holes to form a source and a drain.

For each of the TFTs proposed in the present invention, the dual-layer insulating laminate enables improvements in its performance by enhancing the interface properties and repairing interface state defects in the semiconductor layers.

### BRIEF DESCRIPTION OF THE DRAWINGS

FIG. 1 is a structural illustration of a thin film transistor (TFT) of the prior art.

FIG. 2 is a structural illustration of a TFT according to a first embodiment of the present invention.

FIG. 3 is a diagram showing off-state current statistics of the TFT according to the first embodiment of the present invention and the existing TFT.

FIG. 4 is a diagram showing sub-threshold swing (SS) factor statistics of the TFT according to the first embodiment of the present invention and the existing TFT.

FIG. 5 is a diagram showing mobility statistics of the TFT according to the first embodiment of the present invention and the existing TFT.

FIG. 6 is a structural illustration of a TFT according to a second embodiment of the present invention.

FIG. 7 is a structural illustration of a TFT according to a third embodiment of the present invention.

### DETAILED DESCRIPTION

Specific embodiments of thin film transistors (TFTs) and methods for manufacturing them according to the present invention will be described in detail below with reference to the accompany drawings. Features and advantages of the invention will be more apparent from the following detailed description, and from the appended claims. Note that the figures are provided in a very simplified form not necessarily presented to scale, with the only intention to facilitate convenience and clarity in explaining the embodiments.

### Embodiment 1

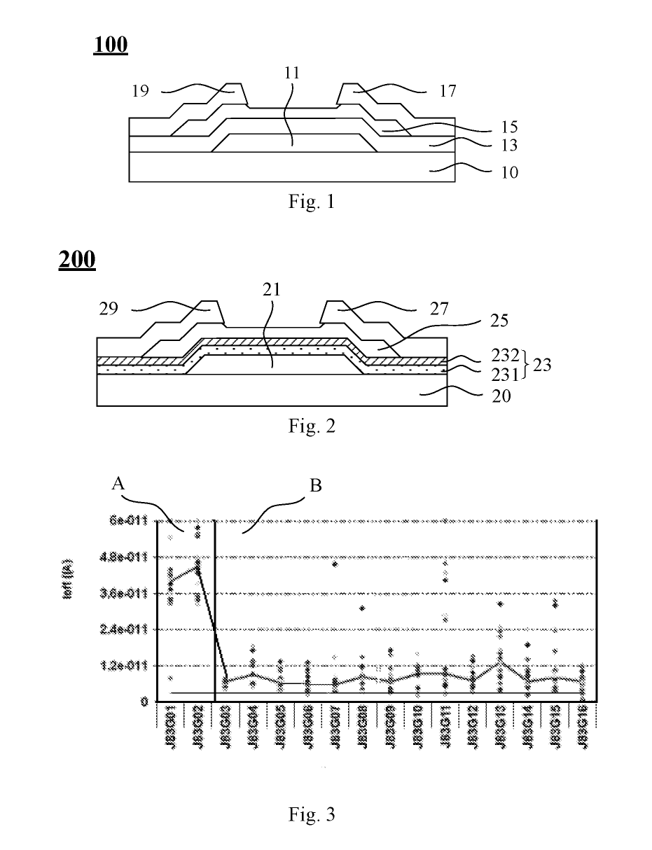

Reference is now made to FIG. 2, a structural illustration of a TFT according to a first embodiment of the present invention. As shown in FIG. 2, the TFT 200 includes: a gate 21 on a substrate 20; an insulating laminate 23 on the gate 21; a semiconductor layer 25 on the insulating laminate 23; and a source 27 and a drain 29 on the semiconductor layer 25. The source 27 and the drain 29 are located on and connected to respective lateral edges of the semiconductor layer 25. The insulating laminate 23 includes a first insulating layer 231 and a second insulating layer 232, wherein the second insulating layer 232 is formed between the first insulating layer 231 and the semiconductor layer 25.

In particular, the first insulating layer 231 is a tetraethyl orthosilicate (TEOS) layer, while the second insulating layer 232 is a silicon oxynitride (SiOₓN_{y}) layer. Both of the first insulating layer 231 and the second insulating layer 232 are formed by chemical vapor deposition (CVD).

In this embodiment, the insulating laminate 23 is a dual-layer laminate, i.e., wherein the first layer is the first insulating layer 231 and the second layer is the second insulating layer 232. The second insulating layer 232 is in direct contact with the semiconductor layer 25. With the second insulating layer 232, it is possible to provide more hydrogen and repair interface state defects of the semiconductor layer 25, thereby improving the interface state density and enhancing the performance of the TFT 200. This will be described in greater detail below in connection with the fabrication method.

Preferably, the first insulating layer 231 and the second insulating layer 232 both have a thickness comprised between 1 nanometer (nm) and 80 nm. Further, the thicknesses of the first insulating layer 231 and the second insulating layer 232 are comprised between 2 nm and 4 nm. For example, the thickness of the first insulating layer 231 or second insulating layer 232 may be 2.2 nm, 2.5 nm, 2.8 nm, 3 nm, 3.2 nm, 3.5 nm or 3.8 nm.

The results of experiments show that the TFT with the dual-layer insulating laminate 23 has a lower off-state current (I_{off}), a reduced SS factor and an improved mobility.

FIG. 3 shows I_{off} statistics of the TFT according to the first embodiment of the present invention and the existing TFT. The figure is divided into two sections indicated at A and B by a vertical line. As shown in FIG. 3, the existing TFT (corresponding to the section A in the figure) has a high I_{off} of about 40 pA, while the TFT according to the first embodiment of the present invention (corresponding to the section B in the figure) has a much lower J of about 6 pA.

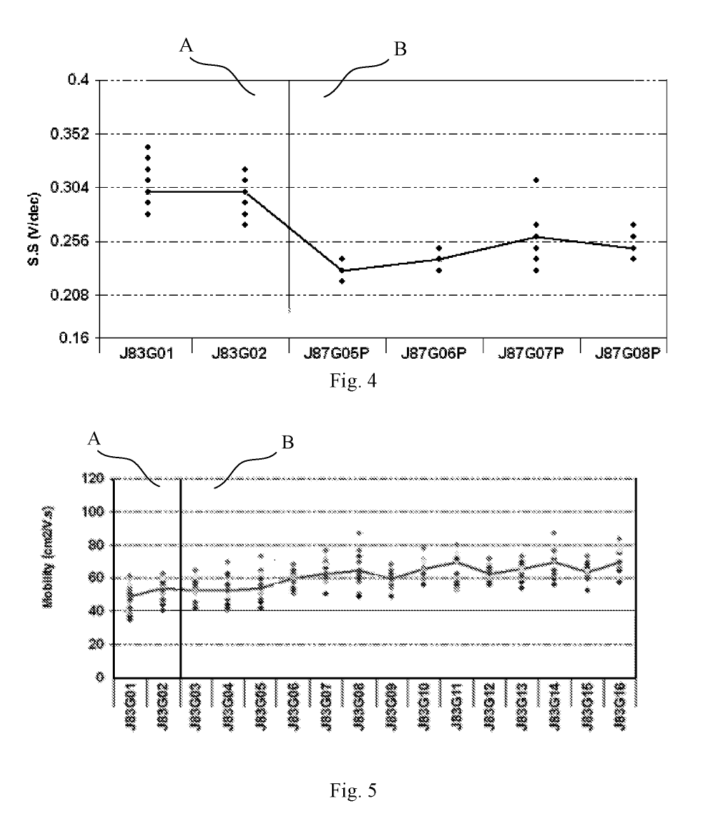

FIG. 4 shows SS factor statistics of the TFT according to the first embodiment of the present invention and the existing TFT. The figure is also divided into sections A and B by a vertical line. As shown in FIG. 4, the existing TFT (corresponding to the section A in the figure) has a high SS factor ranging from 0.3 to 0.4, while the TFT according to the first embodiment of the present invention (corresponding to the section B in the figure) has a significantly reduced SS factor of from 0.2 to 0.3.

FIG. 5 shows mobility statistics of the TFT according to the first embodiment of the present invention and the existing TFT. The figure is also divided into sections A and B by a vertical line. As shown in FIG. 5, the existing TFT (corresponding to the section A in the figure) has a low mobility substantially within the range from 40 to 60, while the TFT according to the first embodiment of the present invention (corresponding to the section B in the figure) has a significantly higher mobility of substantially from 60 to 80.

Therefore, the TFT 200 according this embodiment has significantly improved properties compared to the existing TFT.

In this embodiment, there is also provided a method of fabricating the TFT. With continued reference to FIG. 2, the method of fabricating the TFT includes:

step 1: providing a substrate 20 and forming a gate 21 on the substrate 20;

step 2: forming a first insulating layer 231 on the gate 21 by a first CVD process;

step 3: forming a second insulating layer 232 on the first insulating layer 231 by a second CVD process;

step 4: forming a semiconductor layer 25 on the second insulating layer 232; and

step 5: forming a source 27 and a drain 29 on the semiconductor layer 25.

Specifically, at first, a substrate 20 is provided, which may be a transparent glass substrate, a transparent plastic substrate or a semiconductor substrate.

Subsequently, a gate 21 is formed on the substrate 20. The gate 21 may be formed from a known material by a known process. Here, a detailed description of the known material and process is deemed unnecessary.

Afterward, a first CVD process is carried out to form a first insulating layer 231 on the gate 21. The first insulating layer 231 is a TEOS layer, while oxygen (O₂) may be used as a working gas in the first CVD process.

After that, a second CVD process is performed to form a second insulating layer 232 on the first insulating layer 231. The second insulating layer 232 is a silicon oxynitride (SiOₓN_{y}) layer. In the second CVD process, a mixture of SiH₄, NH₃, N₂ and N₂O is used as a working gas. Here, NH₃ is present in the mixture at a molar ratio comprised between 0.8 and 0.96. In other words, the ratio of the number of moles of NH₃ to the mixture is between 0.8 and 0.96. Preferably, NH₃ is present in the mixture at a molar ratio of 0.93.

The first insulating layer 231 and the second insulating layer 232 constitute an insulating laminate 23.

Thereafter, a semiconductor layer 25 is formed on the second insulating layer 232. The semiconductor layer 25 may be, for example, a polycrystalline silicon layer or an amorphous silicon layer. The semiconductor layer 25 may be formed from a known material by a known process. Here, a detailed description of the known material and process is deemed unnecessary.

Lastly, a source 27 and a drain 29 are formed on the semiconductor layer 25. The source 27 and the drain 29 are located at and connected to opposing lateral edges of the semiconductor layer 25.

As can be known from the foregoing description of the TFT fabrication method, the hydrogen-containing gases SiH₄ and NH₃ used in the deposition of the second insulating layer 232 serve as a source of hydrogen ions which will diffuse from the inside of the second insulating layer 232 to the interface of the semiconductor layer 25 during a subsequent annealing process, resulting in an increased interface state density and improved performance of the TFT 200.

### Embodiment 2

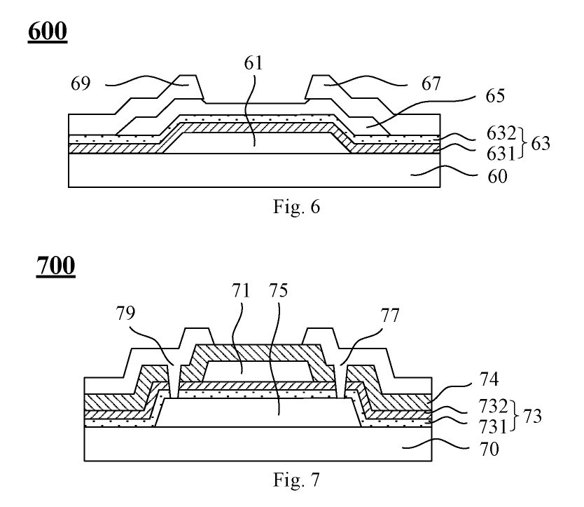

FIG. 6 is a structural illustration of a TFT according to a second embodiment of the present invention. As shown in the figure, the TFT 600 includes: a gate 61 on a substrate 60; an insulating laminate 63 on the gate 61; a semiconductor layer 65 on the insulating laminate 63; and a source 67 and a drain 69 on the semiconductor layer 65. The source 67 and the drain 69 are located on and connected to respective lateral edges of the semiconductor layer 65. The insulating laminate 63 includes a first insulating layer 631 and a second insulating layer 632, wherein the second insulating layer 632 is formed between the first insulating layer 631 and the semiconductor layer 65.

This embodiment differs from Embodiment 1 in that the first insulating layer 631 is a silicon oxynitride (SiOₓN_{y}) layer, with the second insulating layer 632 being a tetraethyl orthosilicate (TEOS) layer. In other words, although the insulating laminate 63 of this embodiment is also a dual-layer laminate as in Embodiment 1, the semiconductor layer 65 is in direct contact with TEOS in accordance with this embodiment. As TEOS itself has a good interface state density, better contact is enabled between the insulating laminate 63 and the semiconductor layer 65, which can lead to an improvement in the interface state density of the semiconductor layer 65.

On the other hand, as described above in Embodiment 1, the hydrogen-containing gases SiH₄ and NH₃ used in the deposition of the first insulating (SiOₓN_{y}) layer 631 serve as a source of hydrogen ions which will diffuse through the second insulating layer 632 to the interface of the semiconductor layer 65 during a subsequent annealing process and repair interface state defects in the semiconductor layer 65, resulting in an increased interface state density and improved performance of the TFT 600.

The thicknesses of the first and second insulating layers 631, 632 are within the same range as those of Embodiment 1, and the fabrication of the TFT 600 differs from that of Embodiment 1 only in that steps 2 and 3 are carried out in a reverse order. In addition, the deposition of the first insulating (SiOₓN_{y}) layer 631 and the second insulating (TEOS) layer 632 in this embodiment is accomplished with the same working gas with the same composition as Embodiment 1, and a detailed description thereof is therefore deemed unnecessary.

In this embodiment, since the second insulating (TEOS) layer 632 is in direct contact with the semiconductor layer 65, and as the interface of the semiconductor layer 65 is repaired by hydrogen ions from the first insulating (SiOₓN_{y}) layer 631, the improvement in the interface state density is doubled and the TFT 600 according to this embodiment therefore has better performance than that of Embodiment 1.

### Embodiment 3

FIG. 7 is a structural illustration of a TFT according to a third embodiment of the present invention. Unlike those of Embodiments 1 and 2 in each of which the gate is formed as one of the bottom most components, in a TFT according to this embodiment, a gate is formed as one of the topmost components.

As shown in FIG. 7, the TFT 700 includes: a semiconductor layer 75 on a substrate 70; an insulating laminate 73 on the semiconductor layer 75; a gate 71 on the insulating laminate 73; a dielectric layer 74 covering the gate 71; and a source 77 and a drain 79 on the dielectric layer 74. The source 77 and the drain 79 are formed on opposing sides of the gate 71 and both penetrate the dielectric layer 74 and the insulating laminate 73 to connect to the semiconductor layer 75. The insulating laminate 73 includes a first insulating layer 731 and a second insulating layer 732, and the first insulating layer 731 is between the second insulating layer 732 and the semiconductor layer 75.

Preferably, the first insulating layer 731, which is in direct contact with the semiconductor layer 75, is a tetraethyl orthosilicate (TEOS) layer, and the second insulating layer 732 is a silicon oxynitride (SiOₓN_{y}) layer. The first and second insulating layers 731, 732 are formed using CVD processes which are the same as those of Embodiment 1 in terms of working gas and process parameters, and the thicknesses of the first and second insulating layers 731, 732 are the same as those of Embodiment 1.

In this embodiment, the first insulating (TEOS) layer 731 is in direct contact with the semiconductor layer 75, and the interface of the semiconductor layer 75 is repaired by hydrogen ions from the second insulating (SiOₓN_{y}) layer 732. Therefore, improvement in the interface state density is doubled and the TFT 700 has better performance.

It can be easily appreciated by those skilled in the art that it is also possible that the first insulating layer 731 according to this embodiment is a silicon oxynitride (SiOₓN_{y}) layer with the second insulating layer 732 being a tetraethyl orthosilicate (TEOS) layer. In this way, the interface state density of the semiconductor layer 75 and hence the electrical characteristics of the TFT can also be improved by repairing the interface state defects between the semiconductor layer 75 and the insulating laminate 73 with hydrogen ions from the silicon oxynitride layer.

A method of fabricating the TFT according to this embodiment will be briefed below with reference to FIG. 7. The method includes:

step 1: providing a substrate 70 and forming a semiconductor layer 75 on the substrate 70;

step 2: forming a first insulating layer 731 on the semiconductor layer 75 by using a first CVD process:

step 3: forming a second insulating layer 732 on the first insulating layer 731 by using a second CVD process;

step 4: forming a gate 71 on the second insulating layer 732;

step 5: forming a dielectric layer 74 covering the gate 71; and

step 6: forming a source 77 and a drain 79 on the dielectric layer 74.

Step 1 of this embodiment in which a semiconductor layer 75 is formed is similar to step 4 of Embodiment 1, steps 2 and 3 of this embodiment are similar to steps 2 and 3 of Embodiment 1, and step 4 of this embodiment in which a gate 71 is formed is similar to step 1 of Embodiment 1. Therefore, these steps will be not be described in further detail.

Subsequent to the formation of the gate 71, the dielectric layer 74 is so formed to cover the gate 71 and optionally the surface of the insulating laminate 73. The dielectric layer 74 is formed of, for example, silicon oxide.

After that, a source 77 and a drain 79 are formed on the dielectric layer 74. The formation of the source 77 and the drain 79 includes etching the dielectric layer 74 and the insulating laminate 73 to form contact holes leading to the semiconductor layer 75 and filling metal(s) in the contact holes. This can be accomplished with existing processes which are not detailed herein for the sake of brevity.

In summary, for each of the TFTs proposed in the present invention, the dual-layer insulating laminate enables improvements in its performance by enhancing the interface properties and repairing interface state defects in the semiconductor layers.

The preferred embodiments presented above are merely examples and are in no way meant to limit the present invention. Any changes or modifications made by those of ordinary skill in the art in light of the above teachings of the present invention are considered to fall within the scope of the appended claims.

1. A thin film transistor, comprising: a gate formed on a substrate; an insulating laminate formed on the gate; a semiconductor layer formed on the insulating laminate; and a source and a drain formed on the semiconductor layer, the source and the drain being located at and connected to opposing lateral edges of the semiconductor layer,
wherein the insulating laminate comprises a first insulating layer and a second insulating layer, the second insulating layer being located between the first insulating layer and the semiconductor layer.

2. The thin film transistor of claim 1, wherein the first insulating layer is a tetraethyl orthosilicate layer, and wherein the second insulating layer is a silicon oxynitride layer.

3. The thin film transistor of claim 1, wherein the first insulating layer is a silicon oxynitride layer, and wherein the second insulating layer is a tetraethyl orthosilicate layer.

4. (canceled)

5. The thin film transistor of claim 1, wherein each of the first insulating layer and the second insulating layer has a thickness comprised between 1 nm and 80 nm.

6. A method of manufacturing the thin film transistor of claim 1, comprising:
providing a substrate and forming a gate on the substrate;
forming a first insulating layer on the gate by a first chemical vapor deposition process;
forming a second insulating layer on the first insulating layer by a second chemical vapor deposition process;
forming a semiconductor layer on the second insulating layer; and
forming a source and a drain on the semiconductor layer.

7. The method of manufacturing the thin film transistor of claim 6, wherein the first insulating layer is a tetraethyl orthosilicate layer and the second insulating layer is a silicon oxynitride layer; wherein the first chemical vapor deposition process for forming the tetraethyl orthosilicate layer uses oxygen as a working gas and the second chemical vapor deposition process for forming the silicon oxynitride layer uses a mixed gas of SiH₄, NH₃, N₂ and N₂O as a working gas.

8. The method of manufacturing the thin film transistor of claim 6, wherein the first insulating layer is a silicon oxynitride layer and the second insulating layer is a tetraethyl orthosilicate layer; wherein the second chemical vapor deposition process for forming the tetraethyl orthosilicate layer uses oxygen as a working gas and the first chemical vapor deposition process for forming the silicon oxynitride layer uses a mixed gas of SiH₄, NH₃, N₂ and N₂O as a working gas.

9-10. (canceled)

11. The method of manufacturing the thin film transistor of claim 7, wherein NH₃ is present in the mixed gas at a molar ratio comprised between 0.8 and 0.96.

12. The method of manufacturing the thin film transistor of claim 6, wherein each of the first insulating layer and the second insulating layer has a thickness comprised between 1 nm and 80 nm.

13. A thin film transistor, comprising: a semiconductor layer formed on a substrate; an insulating laminate formed on the semiconductor layer; a gate formed on the insulating laminate; a dielectric layer covering the gate; and a source and a drain formed on the dielectric layer, the source and the drain being located at opposing later edges of the gate and penetrating through the dielectric layer and the insulating layer to connect to the semiconductor layer,
wherein the insulating laminate comprises a first insulating layer and a second insulating layer, and wherein the first insulating layer is located between the second insulating layer and the semiconductor layer.

14. The thin film transistor of claim 13, wherein the first insulating layer is a tetraethyl orthosilicate layer, and wherein the second insulating layer is a silicon oxynitride layer.

15. The thin film transistor of claim 13, wherein the first insulating layer is a silicon oxynitride layer, and wherein the second insulating layer is a tetraethyl orthosilicate layer.

16. (canceled)

17. The thin film transistor of claim 13, wherein each of the first insulating layer and the second insulating layer has a thickness comprised between 1 nm and 80 nm.

18. A method for manufacturing the thin film transistor of claim 13, comprising:
providing a substrate and forming a semiconductor layer on the substrate;
forming a first insulating layer on the semiconductor layer by a first chemical vapor deposition process;
forming a second insulating layer on the first insulating layer by a second chemical vapor deposition process;
forming a gate on the second insulating layer;
forming a dielectric layer covering the gate;
etching the dielectric layer, the second insulating layer and the first insulating layer and forming contact holes at opposing lateral edges of the gate, the contact holes leading to the semiconductor layer; and
filling metal(s) in the contact holes to form a source and a drain.

19. The method of manufacturing the thin film transistor of claim 18, wherein the first insulating layer is a tetraethyl orthosilicate layer and the second insulating layer is a silicon oxynitride layer; wherein the first chemical vapor deposition process for forming the tetraethyl orthosilicate layer uses oxygen as a working gas and the second chemical vapor deposition process for forming the silicon oxynitride layer uses a mixed gas of SiH₄ NH₃, N₂ and N₂O as a working gas.

20. The method of manufacturing the thin film transistor of claim 18, wherein the first insulating layer is a silicon oxynitride layer and the second insulating layer is a tetraethyl orthosilicate layer; wherein the second chemical vapor deposition process for forming the tetraethyl orthosilicate layer uses oxygen as a working gas and the first chemical vapor deposition process for forming the silicon oxynitride layer uses a mixed gas of SiH₄, NH₃, N₂ and N₂O as a working gas.

21-22. (canceled)

23. The method of manufacturing the thin film transistor of claim 19, wherein NH₃ is present in the mixed gas at a molar ratio comprised between 0.8 and 0.96.

24. The method of manufacturing the thin film transistor of claim 18, wherein each of the first insulating layer and the second insulating layer has a thickness comprised between 1 nm and 80 nm.

25. The method of manufacturing the thin film transistor of claim 8, wherein NH₃ is present in the mixed gas at a molar ratio comprised between 0.8 and 0.96.

26. The method of manufacturing the thin film transistor of claim 20, wherein NH₃ is present in the mixed gas at a molar ratio comprised between 0.8 and 0.96.
